(19) United States
(12) Patent Application Publication
(10) Pub. No.: US 2009/0071527 A1
(43) Pub. Date: Mar. 19, 2009

(54) SOLAR ARRAYS WITH GEOMETRIC-SHAPED, THREE-DIMENSIONAL STRUCTURES AND METHODS THEREOF

(75) Inventors: Douglas H. AXTELL, Rochester, NY (US); Steven SCOTT, Pittsford, NY (US)

Correspondence Address: NIXON PEABODY LLP - PATENT GROUP, 1100 CLINTON SQUARE, ROCHESTER, NY, 14604, US

(73) Assignee: Reflexite Corporation, Avon, CT (US)

(21) Appl. No.: 12/233,027

(22) Filed: Sep. 18, 2008

Related U.S. Application Data
(60) Provisional application No. 60/994,164, filed on Sep. 18, 2007.

(51) Int. Cl. H01L 31/042

(52) U.S. Cl. 136/244

(57) ABSTRACT

A solar array system has a plurality of geometric-shaped, three-dimensional structures on a surface of a substrate. At least one surface of one of the geometric-shaped, three-dimensional structures is sloped with respect to the surface of the substrate. At least one photovoltaic conversion layer is on at least a portion of one the geometric-shaped, three-dimensional structures.

This application claims the benefit of U.S. Provisional Patent Application Ser. No. 60/994,164, filed Sep. 18, 2007, which is hereby incorporated by reference in its entirety.

### FIELD OF THE INVENTION

This invention generally relates to solar arrays and, more particularly, to solar arrays with geometric-shaped, three-dimensional structures and methods thereof.

### BACKGROUND

Photovoltaic devices convert incident light into electrical energy. The most commonly available photovoltaic devices use a photovoltaic conversion layer of amorphous silicon with sufficient thickness that these devices transmit no light.

One type of photovoltaic device only uses organic components and is referred to as an organic solar cell. There are three major types of organic solar cells: single layer; double layer; and blends. An example of a single layer type is described in U.S. Pat. No. 4,127,738, assigned to Exxon Research entitled, “Photovoltaic device containing an organic layer.” The double layer type is described in an article, entitled, “Two-layer organic photovoltaic cell” C. W. Tang, Appl. Phys. Lett. Vol. 48, pp. 183-185 (1986). An example of the blend type is described in U.S. Pat. No. 5,670,791, entitled, “Photo-responsive device with a photo-responsive zone comprising a polymer blend”, assigned to U.S. Philips Corporation.

Another type of photovoltaic device incorporates conjugated polymers or hybrid architecture with dispersed interfaces, incorporating C₆₀ structures or quantum rods of inorganic semiconductors. An example of a photovoltaic device incorporating conjugated polymers is described in, J. H. Burroughs, et al, Nature, Vol. 347, (1990), pp. 539-541 and G. Yu et al, Science, Vol. 270, 1789-1791, (1995).

A newer type of photovoltaic device is fabricated on a transparent support and incorporates a transparent front electrode immediately adjacent the support, with one or more photovoltaic conversion layers situated on the side of the transparent electrode furthest from the support. With this type of photovoltaic device, there are several types of architecture. Perhaps the best known is the Gratzel Cell as described in Nature, volume 353, pp. 737-740 in 1991, which is an example of a photoelectrochemical cell. A review of this photoelectrochemical cell is provided in an article entitled, “Photoelectrochemical cells,” Nature, volume 414, pp. 338-344 on 15 Nov. 2001.

With these newer types of photovoltaic devices, high transparency is required to minimize light loss by allowing as high a proportion of incident light as possible to pass through to the photoactive region. High conductivity also is required to minimize resistive losses as photoelectrons travel from their point of creation in the photoactive region to the interface with the transparent electrode and then through the transparent electrode to an external circuit or load. Further, although not required, plastic material typically is used for the support rather than glass because plastic reduces manufacturing costs and makes the photovoltaic device more rugged. Unfortunately, when plastic material is used for the transparent conductive layer which forms the transparent electrode, greater resistive losses occur than with glass. These resistive losses occur because the choice of materials for the transparent electrode is restricted to those which have the appropriate physical properties and which are compatible with roll to roll manufacturing processes for coating thin layers on plastic.

One approach to reducing resistive losses with the use of transparent electrodes made with plastic is to use a network of narrow opaque tracks of highly conductive material, for example metal, adjacent to the conductive transparent layer. The metallic network or grid is connected to the external circuit. In this way, the photoelectrons only travel a short distance through the transparent electrode before reaching the highly conductive metallic network or grid. Unfortunately, a disadvantage of this approach is that the metallic grid impedes the incident light from reaching the photovoltaic conversion layers and effectively reduces the active area of the photovoltaic device.

Currently, existing photovoltaic devices, such as those described above, have a low efficiency of about 10% to near 40% for the best in class designs. Typically, these photovoltaic devices are formed on silicon wafers which are rigid, smooth, and flat. The low efficiency in these prior solar arrays and cells can be attributed to several mechanisms: approximately 20-30% of the potential energy is lost to reflection from the coatings in the layers on the photovoltaic devices; potential energy is lost to poor quantum efficiency of the charge generating layers; and potential energy is lost to charge transport or internal resistance. Accordingly, there is a need to enhance light capturing efficiency in photovoltaic devices.

In the art of image sensor array fabrication where the photosensitive layer is pixilated, it is well known to use a single lens structure associated with each pixel to gather light from an area larger than the active area of the pixel. U.S. Pat. No. 4,694,185, assigned to Eastman Kodak Company, describes a method for providing lenses to guide light onto each pixel of a previously fabricated image sensor array.

With photovoltaic devices, a method for enhancing light capturing efficiency is described in U.S. Pat. No. 6,440,769, assigned to The Trustees of Princeton University. More specifically, this method discloses fabricating an array of parabolic reflective concentrators on the surface of a photovoltaic device. This method describes an optical geometry that overcomes the relatively poor optical absorption of the photovoltaic device by allowing multiple internal reflections to enable incident light to pass through it several times. As a result, the probability of absorption of the light by the photovoltaic conversion layers is improved. The design of the concentrating structures draws on concepts presented in, “The Optics of Nonimaging Concentrators,” by W. T. Welford and R. Winston, 1978, Academic Press Inc., especially Chapter 8 and also in High Collection Nonimaging Optics, 1989, by the same authors and publisher, especially pp 172-179.

Another method for enhancing the light capturing efficiency is described in U.S. Pat. No. 5,926,319 assigned to Nashua Corporation. This patent describes the use of a microlens screen situated in front of a semiconductor solar cell to concentrate the incident light to a plurality of spots on the semiconductor. According to this patent, for a given average illumination of the exposed semiconductor surface, a higher electrical output from the device is obtained than with an arrangement where the same average illumination is provided uniformly across the semiconductor surface.

A further method for enhancing the light capturing efficiency is described in US Patent Application Publication No. 20070025139, assigned to Georgia Tech Research Institute (GTRI). This publication discusses the use of carbon nanotube arrays to increase the surface area of the solar array by fabricating the array in a three-dimensional form making 40 micron square and 100 micron tall pillars with vertical sides placed in an array. This array uses silicon wafers as the backplane to form rigid photovoltaic cells. Unfortunately, with this design the vertical sides reduce the efficiency of these pillars in harvesting photons.

### BRIEF DESCRIPTION OF THE DRAWINGS

FIG. 1 is a perspective view of a solar array with truncated, hexagonal-shaped structures in accordance with embodiments of the present invention;

FIG. 2 is a perspective view of another solar array with truncated, hexagonal-shaped structures in accordance with other embodiments of the present invention;

FIG. 3 is a perspective view of a solar array with truncated, square-shaped structures in accordance with other embodiments of the present invention; and

FIG. 4 is a perspective view of a solar array with truncated, triangular-shaped structures in accordance with other embodiments of the present invention.

### DETAILED DESCRIPTION

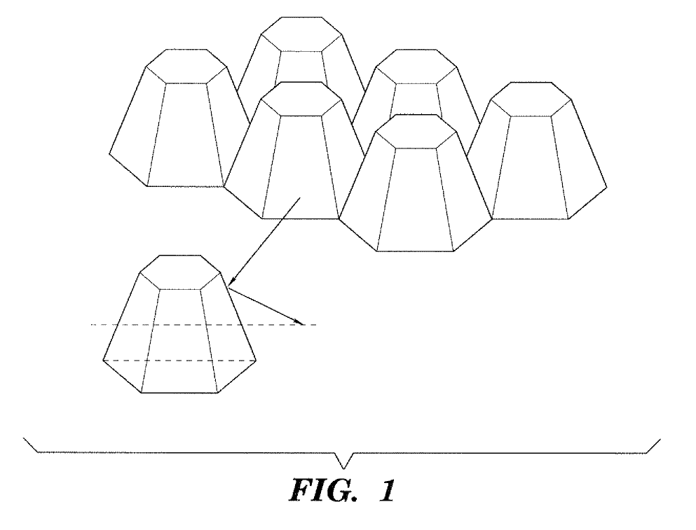

Solar arrays or cells with truncated, geometric shaped structures in accordance with embodiments of the present invention are illustrated in FIGS. 1-4. Each of these solar arrays is a micro-structured device that includes a plurality of truncated, geometric-shaped structures with sloped, multi-faceted surfaces on a substrate, although the solar arrays can include other numbers and types of separate structures and elements in other combinations and configurations. The present invention provides a number of advantages including providing a solar array with higher efficiency when compared against prior solar arrays or cells.

More specifically, the present invention increases light capturing efficiency by providing solar arrays or cells with truncated, geometric-shaped structures with sloped, multi-faceted surfaces that have a photovoltaic coating or conversion layer. With these solar arrays or cells, incident light on one of the sloped surfaces which is reflected can intersect with and be captured by the photovoltaic coating or conversion layer on another sloped surface. Capturing this reflected light with this design increases the energy capture potential of the solar array or cell to about 90%.

Providing solar arrays or cells with these truncated, geometric-shaped structures with sloped, multi-faceted surfaces also substantially increases the light capturing surface area, so the charge generating area in the solar array or cell can be significantly increased without increasing the footprint of the solar array or cell. For example, if the charge generating coatings are placed upon a high aspect structure that has 50-100 um altitude above the lowest portions of the structure, with walls sloped inwards from orthogonal, the surface area can be increased by a significant factor as illustrated in the embodiments shown in FIGS. 1-4. Lower aspect geometric-shaped structures in accordance with other embodiments, will also provide the same benefits, however the increase in surface area will diminish as the structure aspect ratio decreases. In these embodiments of the present invention, the plurality of geometric-shaped, three-dimensional structures have a height to width ratio between about 5:1 to about 1:5 to provide a substantial improvement in light capturing efficiency, although other height to width ratios could be used. Assuming the same current per unit area is generated as in a prior art solar array, a solar array in accordance with embodiments of the present invention will increase the energy output two-fold without increasing the footprint, due to the increased surface area.

Another advantage of the present invention is that the sloped, multifaceted surfaces or sidewalls on the geometric-shaped structures enable the solar array to maintain a higher efficiency when the solar array is not in perfect alignment with the sun. Since the altitude and azimuth of the sun changes significantly with the season in northern latitudes, a solar array with geometric-shaped structures in accordance with embodiments of the present invention will provide more uniform energy output. This is particularly beneficial for applications with fixed position solar arrays or cells, such as those powering safety devices, signs and navigational signals. By way of example, there is approximately a 40 degree altitude delta, and 50 degree azimuth delta, between two dates separated by six months, i.e. January and July, at 43 degrees of latitude. A solar array in accordance with embodiments of the present invention will be more efficient than a traditional solar array if both are fixed in position with respect to the surface of the earth and it's axis of rotation.

In embodiments of the present invention, creating a three-dimensional multifaceted, sloped surface on a geometric-shaped structure in a solar array means the sloped surface will reflect any light not utilized on the first impact to another otherwise shadowed facet on another surface of the solar array. The surfaces also can be used for charge transport from the conversion of the incident light.

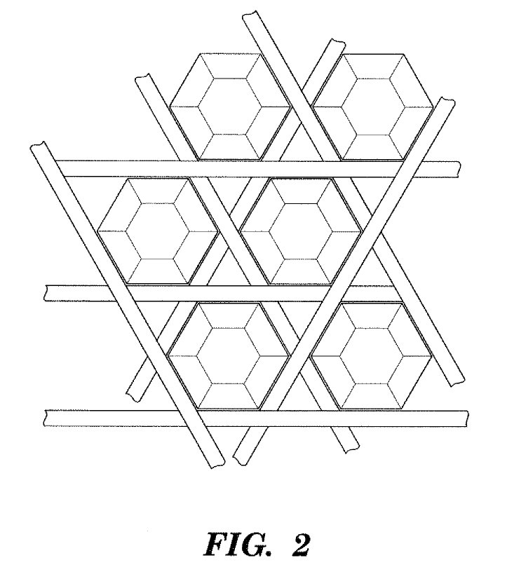

Referring more specifically to FIGS. 1-2, the solar array has a plurality of truncated, hexagonal-shaped structures extending away from a surface of the substrate, although other shaped structures could be used, such as non-geometrically-shaped structures. These structures have sloped, side surfaces, also referred to as walls or facets, for light harvesting. The truncated, hexagonal-shaped structures are formed adjacent to each other as illustrated in the embodiment in FIG. 1 to minimize the overall footprint of the solar array, although other configurations and footprints could be used. For example, to simplify manufacturing the truncated, hexagonal-shaped structures could be separated by tool cutting paths as illustrated in FIG. 2.

In the embodiments illustrated in FIGS. 1 and 2, the sloped, side surfaces are positioned about every 60 degrees and opposing side surfaces are both parallel and 30 degrees, although the side surfaces could have other orientations and configurations. With these sloped, side surfaces, there are many facing surfaces for generating a charge from the light reflected from the initial impact of the solar energy. The sloped, side surfaces of the structure offer more access to the surfaces which makes manufacturing easier for applying other layers on the structures. The hexagonal-shape along with the sloped, side surfaces also enhance light capturing efficiency if the solar array is not optimally aligned with the light source. In these embodiments, the geometric-shaped structures are truncated, although the structures can have other shapes and configurations, such as a non-truncated configuration.

Truncating the geometric-shaped structures provides a number of benefits including providing a flat bearing surface to support the array while protecting the corners of the sloped, side surfaces and the conductive or charge generating interfaces from damage. Additionally, the truncated, geometric shaped structures are less fragile than sharply pointed structures and are easier to apply subsequent coated layers that are necessary to create the charge generating layers in the solar array. Further, truncating the geometric-shaped structures provides a primary charge generating surface with maximum efficiency when the light source is orthogonal to the array.

These geometric-shaped structures are formed from a substrate using a casting, coating, vacuum forming, or extrusion processes, although these structures could be formed from the substrate in other manners or these structures could be formed or otherwise attached on the substrate. The geometric-shaped structures are rigid, although the structures could be made to be flexible and could be laminated for structural, charge carrying, or other purposes. The geometric-shaped structures are between 4 nm and 10 cm in height, although these structures could have other dimensions.

A conductive layer is applied on the geometric-shaped structures and is used to transport the charge generated by the photovoltaic conversion layer or layers, although other number of layers and other types of charge transport systems could be used or no-charge transport layer. For example, the geometric-shaped structures could be made of a conductive material to transport the charge generated by the photovoltaic conversion layer or layers which would eliminate the need for a conductive layer. The conductive material may include at least one of a conductive polymer, UV curable polymer, a thermally cured material, and an extruded material, although other types of materials could be used. Additionally, by way of example the transparent conductors could include a conductive wire grid to assist with the charge transport.

A photovoltaic conversion layer is formed on the sloped, side surfaces of the geometric-shaped structures on the conductive layer, although other types and numbers of photo conversion layers can be formed on the geometric-shaped structures and on other layers, such as directly on the geometric-shaped structures if there is no conductive layer. The photovoltaic conversion layer converts incident light into electrical energy in manners well known to those of ordinary skill in the art and thus will not be described here. The photovoltaic conversion layer includes a layer of CdTe or CdS, although other types of p-n or other charge forming coating could be applied and used to form the charge generating layer and again other numbers of layers or other photovoltaic conversion devices could be used. The photovoltaic conversion layer is formed as a thin film which increases the efficiency of the solar array and improves charge transport efficiency. The photovoltaic conversion layer or layers can be formed using various deposition processes, such as spray, spin, curtain, vacuum deposition or jet processes, which may increase the efficiency of the solar array and provide additional savings through a reduction in materials used in manufacturing. An optional protective coating could also be applied to over the photovoltaic conversion layer, although other types and numbers of or no additional coatings could be applied.

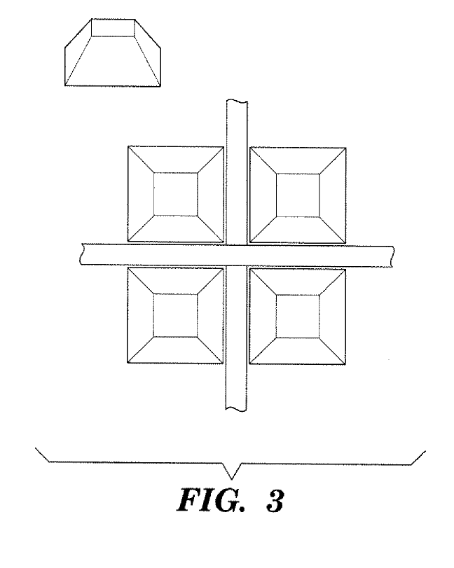

Referring more specifically to FIG. 3, the solar array has a plurality of truncated, square-shaped structures extending away from a surface of the substrate. A single, individual, truncated, square-shaped structure is shown in FIG. 3. The solar array illustrated in FIG. 3 is the same as that described with reference to FIGS. 1 and 2, except as described herein. As a result, elements in FIG. 3 which are the same as those in FIGS. 1 and 2, such as the conductive layer and photovoltaic conversion layer along with their alternatives will not be described again. In the solar array illustrated in FIG. 3, the geometric-shaped structures have a square-shape with the sloped, side surfaces, also referred to as walls or facets, for light harvesting. To simplify manufacturing, the truncated, square-shaped structures also incorporate the tool cutting paths, although other orientations and configurations could be used, such as forming the truncated, square-shaped structures directly adjacent each other.

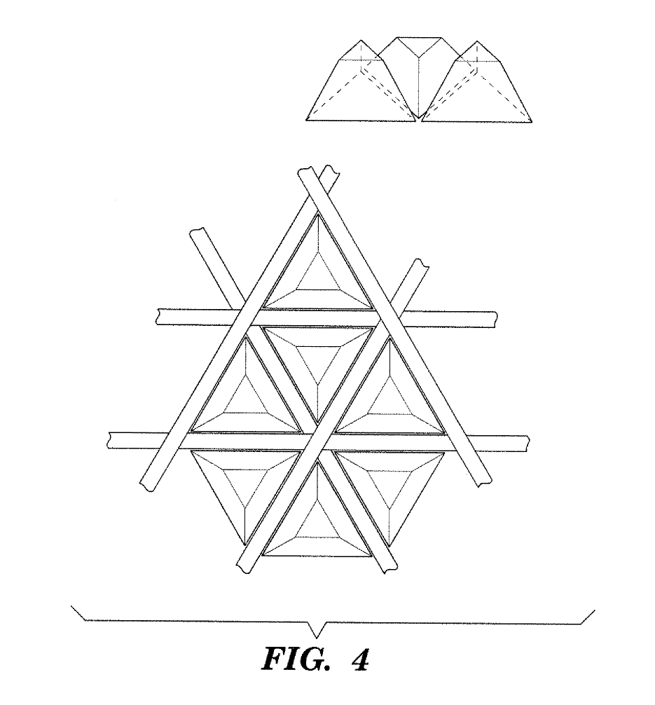

Referring to FIG. 4, the solar array has a plurality of truncated, triangular-shaped structures extending away from a surface of the substrate. The solar array illustrated in FIG. 4 is the same as that described with reference to FIGS. 1 and 2, except as described herein. As a result, elements in FIG. 4 which are the same as in FIGS. 1 and 2, such as the conductive layer and photovoltaic conversion layer along with their alternatives will not be described again. In the solar array illustrated in FIG. 4, the geometric-shaped structures have a triangular-shape with the sloped, side surfaces, also referred to as walls or facets, for light harvesting. Three individual, truncated, triangular-shaped structures are shown in FIG. 3. To simplify manufacturing, the truncated, triangular-shaped structures also incorporate the tool cutting paths, although other orientations and configurations could be used, such as forming the truncated, triangular-shaped structures directly adjacent each other.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. A solar array system comprising:
at least one substrate;
a plurality of geometric-shaped, three-dimensional structures on a surface of the substrate, at least one surface of one of the geometric-shaped, three-dimensional structures is sloped with respect to the surface of the substrate; and
at least one photovoltaic conversion layer on at least a portion of one the geometric-shaped, three-dimensional structures.

2. The system as set forth in claim 1 wherein at least one of the geometric-shaped, three-dimensional structures is truncated.

3. The system as set forth in claim 1 wherein at least one the geometric-shaped, three-dimensional structures has one of a hexagonal, square, and triangular shape.

4. The system as set forth in claim 1 wherein at least one of the plurality of geometric-shaped, three-dimensional structures has a height to width ratio between about 5:1 to about 1:5.

5. The system as set forth in claim 1 wherein the plurality of geometric-shaped, three-dimensional structures are made of a conductive material.

6. The system as set forth in claim 1 further comprising at least one conductor coupled to the at least one photovoltaic conversion layer.

7. The system as set forth in claim 6 wherein the at least one conductive conductor comprises at least one conductive coating on at least a portion of the plurality of geometric-shaped, three-dimensional structures.

8. The system as set forth in claim 1 further comprising at least one path along the surface of the substrate which separates at least two of the geometric-shaped structures.

9. A method for making a solar array system, the method comprising:
forming a plurality of geometric-shaped, three-dimensional structures on a surface of a substrate, at least one surface of one of the geometric-shaped, three-dimensional structures is sloped with respect to the surface of the substrate; and
forming at least one photovoltaic conversion layer on at least a portion of one the geometric-shaped, three-dimensional structures.

10. The method as set forth in claim 9 wherein the forming a plurality of geometric-shaped, three-dimensional structures further comprises forming at least one of the geometric-shaped, three-dimensional structures with a truncated end.

11. The method as set forth in claim 9 wherein the forming a plurality of geometric-shaped, three-dimensional structures further comprises forming at least one of the geometric-shaped, three-dimensional structures to have at least one of a hexagonal, square, and triangular shape.

12. The method as set forth in claim 9 wherein the forming a plurality of geometric-shaped, three-dimensional structures further comprises forming at least one of the geometric-shaped, three-dimensional structures to have a height to width ratio between about 5:1 to about 1:5.

13. The method as set forth in claim 9 wherein the plurality of geometric-shaped, three-dimensional structures are made of a conductive material.

14. The method as set forth in claim 9 further comprising coupling at least one conductor to the at least one photovoltaic conversion layer.

15. The method as set forth in claim 14 wherein the coupling at least one conductor to the at least one photovoltaic conversion layer further comprises forming at least one conductive coating on at least a portion of the plurality of geometric-shaped, three-dimensional structures, wherein the forming at least one photovoltaic conversion layer is formed on the conductive coating.

16. The method as set forth in claim 9 further comprising forming at least one path along the surface of the substrate which separates at least two of the geometric-shaped structures.
